(19) United States
(12) Patent Application Publication
(10) Pub. No.: US 2012/0001157 A1
(43) Pub. Date: Jan. 5, 2012

(54) ORGANIC MATERIAL AND ORGANIC LIGHT EMITTING DEVICE USING THE SAME

(75) Inventors: Yuji HAMADA, Yongin-City (KR); Kwan-Hee LEE, Yongin-City (KR)

(73) Assignee: SAMSUNG MOBILE DISPLAY CO., LTD., Yongin-City (KR)

(21) Appl. No.: 13/163,937

(22) Filed: Jun. 20, 2011

(30) Foreign Application Priority Data
Jun. 21, 2010 (KR) 10-2010-0058776

(51) Int. Cl. H01L 51/54; C07F 3/06; C07F 3/00

(52) U.S. Cl. 257/40; 548/156; 548/149; 548/106; 257/E51.024

(57) ABSTRACT

Disclosed are an organic composition including a compound represented by Chemical Formula 1, and an organic light emitting device including the composition.

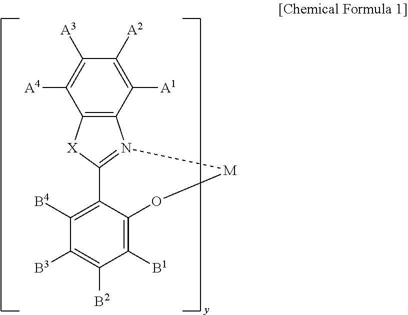

In Chemical Formula 1, A¹, A², A³, A⁴, B¹, B², B³ and B⁴ are independently selected from hydrogen, a C1 to C20 alkyl group, a C1 to C20 alkenyl group, an amino group, a C1 to C20 ether group, a C1 to C20 carboxyl group, a C1 to C20 ester group, a nitro group, a cyano group, a C3 to C30 aromatic group, and a halogen-containing group, provided that at least one of A¹ to A⁴ and at least one of B¹ to B⁴ are a substituted or unsubstituted aromatic group and form a fused ring structure by being bound to an adjacent substituent, M is a divalent or trivalent metal, X is oxygen (O) or sulfur (S), and y is 2 or 3.

### CLAIM PRIORITY

This application claims priority to and the benefit of Korean Patent Application No. 10-2010-0058776 filed in the Korean Intellectual Property Office on Jun. 21, 2010, the entire contents of which are incorporated herein by reference.

### BACKGROUND OF THE INVENTION

1. Field of the Invention

This disclosure relates to an organic material and an organic light emitting device.

2. Description of the Related Art

An organic light emitting device includes two electrodes facing each other and an organic layer interposed between the two electrodes. An organic light emitting device emits light when holes injected from one electrode are combined with electrons injected from the other electrode in an organic layer to produce excitons, and emit energy from the excitons. An organic light emitting device may be applied to various fields including display devices and illuminators. For example, an organic light emitting device has drawn attention as the next generation display device due to wide viewing angles and fast response speed.

### SUMMARY OF THE INVENTION

One aspect of this disclosure provides an organic material having improved electric characteristics.

Another aspect of this disclosure provides an organic light emitting device including the organic material.

According to one aspect of this disclosure, an organic material including a compound represented by Chemical Formula 1 is provided.

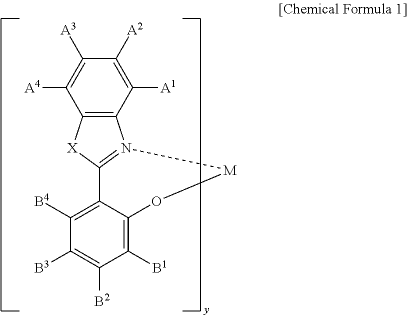

In Chemical Formula 1, A¹, A², A³, A⁴, B¹, B², B³ and B⁴ are independently selected from hydrogen, a C1 to C20 alkyl group, a C1 to C20 alkenyl group, an amino group, a C1 to C20 ether group, a C1 to C20 carboxyl group, a C1 to C20 ester group, a nitro group, a cyano group, a C3 to C30 aromatic group, and a halogen-containing group, provided that at least one of A¹ to A⁴ and at least one of B¹ to B⁴ are a substituted or unsubstituted aromatic group and form a fused ring structure with the aromatic ring attached to the A¹ to A⁴ groups and/or B¹ to B⁴ groups by being bound to an adjacent substituent,
M is a divalent or trivalent metal,
X is oxygen (O) or sulfur (S), and
y is 2 or 3.

According to another aspect of this disclosure, an organic light emitting device is provided with a first electrode and a second electrode facing each other, and an organic layer interposed between the first electrode and the second electrode. The organic layer includes a compound represented by the above Chemical Formula 1.

The organic layer may be an organic emission layer.

At least one of A¹ to A⁴ may include an aromatic group which exists in the same plane as, or is substantially coplanar with, the aromatic group bound to the A¹ to A⁴.

The fused ring structure formed by linking an aromatic group included in at least one of A¹ to A⁴ to the adjacent substituent may include a fluorene structure.

At least one of B¹ to B⁴ may include an aromatic group which exists in the same plane as, or is substantially coplanar with, the aromatic group bound to the B¹ to B⁴.

The fused ring structure formed by linking an aromatic group included in at least one of B¹ to B⁴ to an adjacent substituent may include a fluorene structure.

At least one of A¹ to A⁴ and B¹ to B⁴ and the substituent adjacent to the aromatic group included in at least one of A¹ to A⁴ and B¹ to B⁴ may be represented by the following Chemical Formulas 2 or 3.

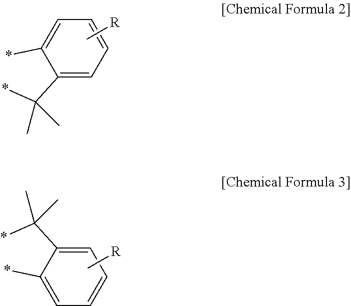

In Chemical Formula 2 and Chemical Formula 3, R is selected from the group consisting of hydrogen, a C1 to C10 alkyl group, an amino group, a C1 to C10 alkyl amino group, a halogen, a hydroxy group, a C1 to C10 alkoxy group, a C2 to C10 ester group, a nitro group, a cyano group, and a substituted or unsubstituted C3 to C24 aromatic group.

The compound may be selected from compounds represented by the following Chemical Formulae 4 to 33.

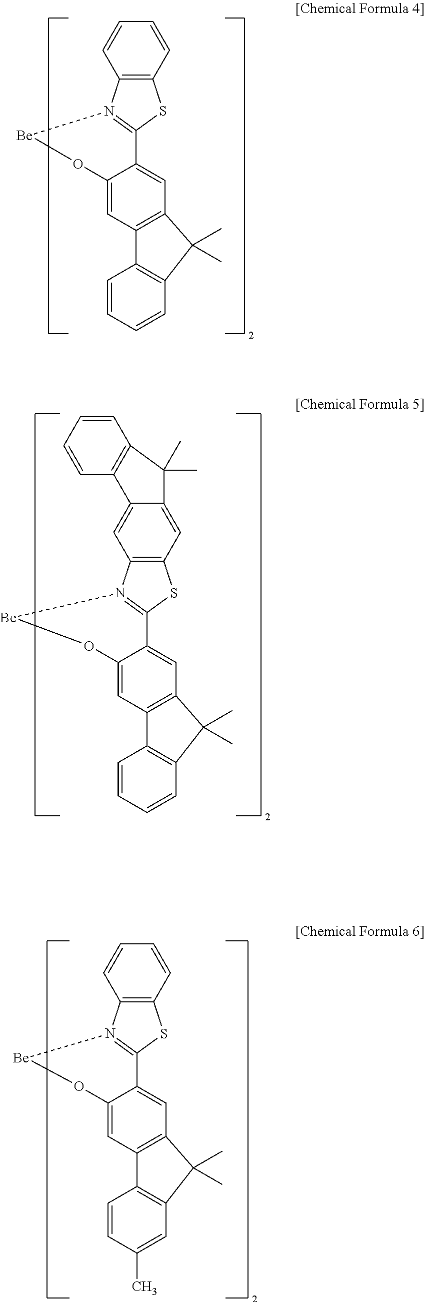

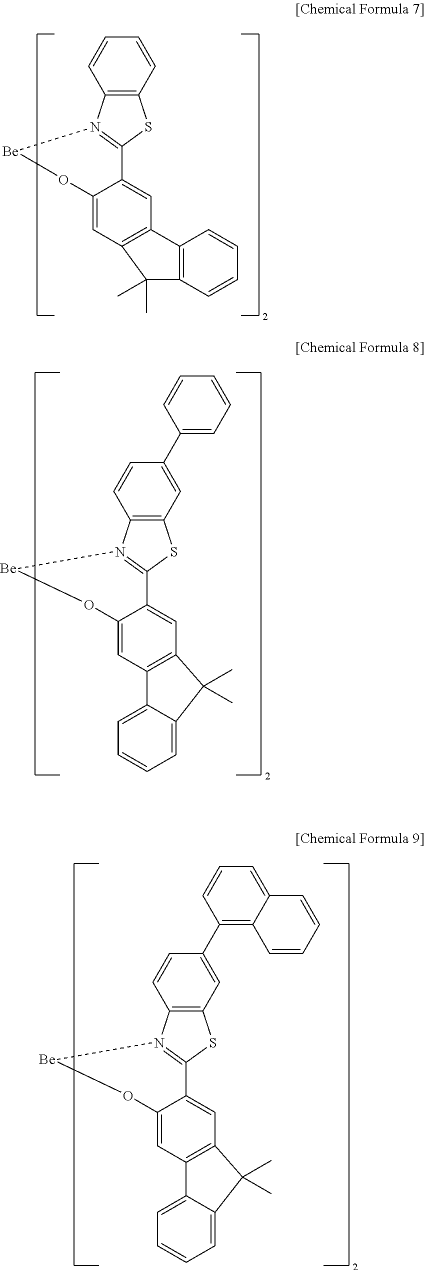

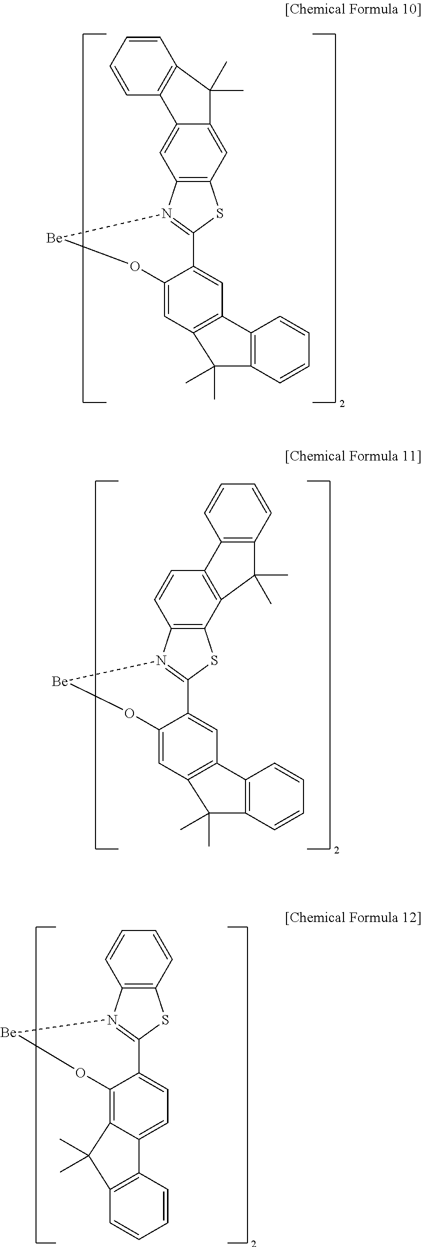

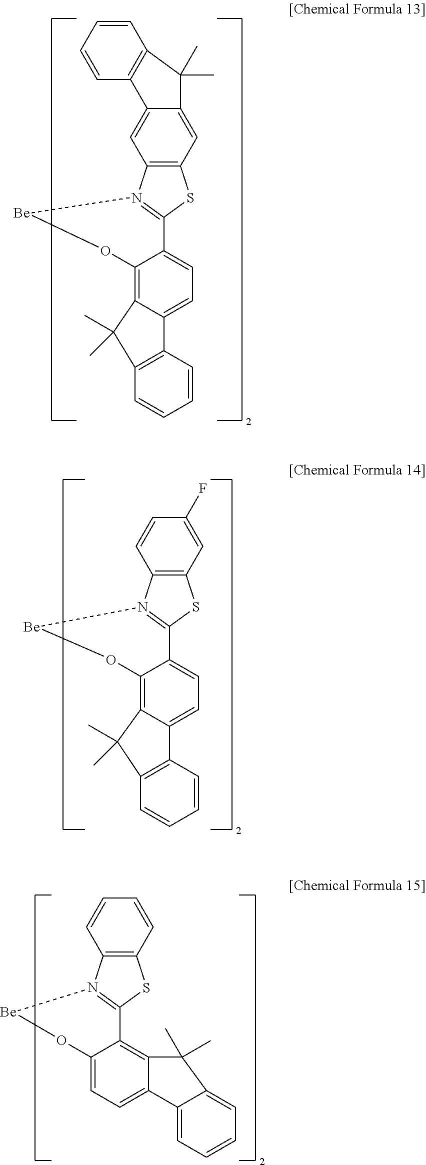

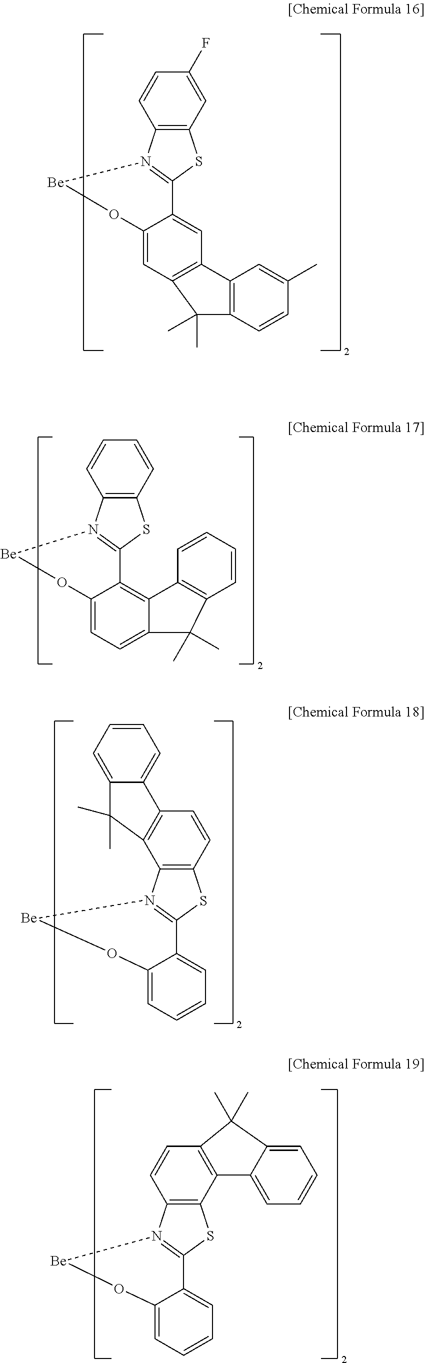

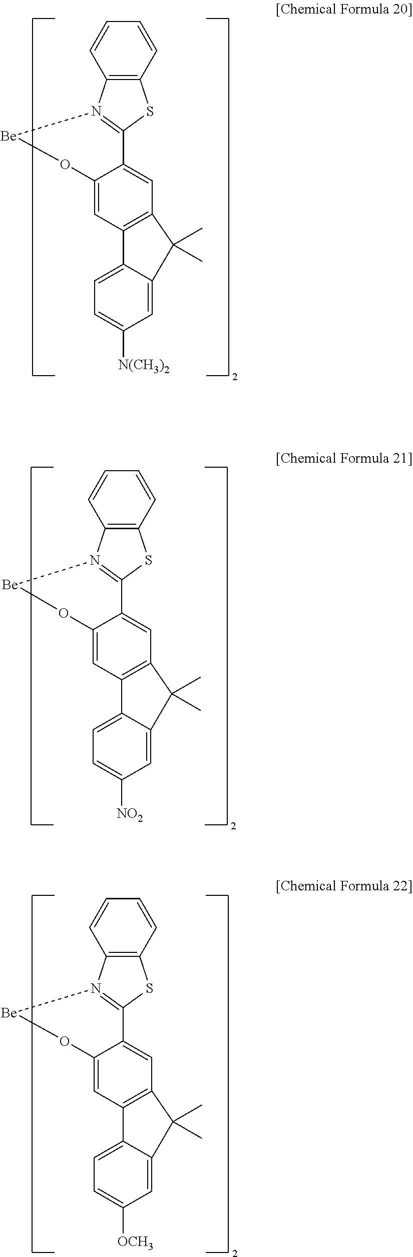

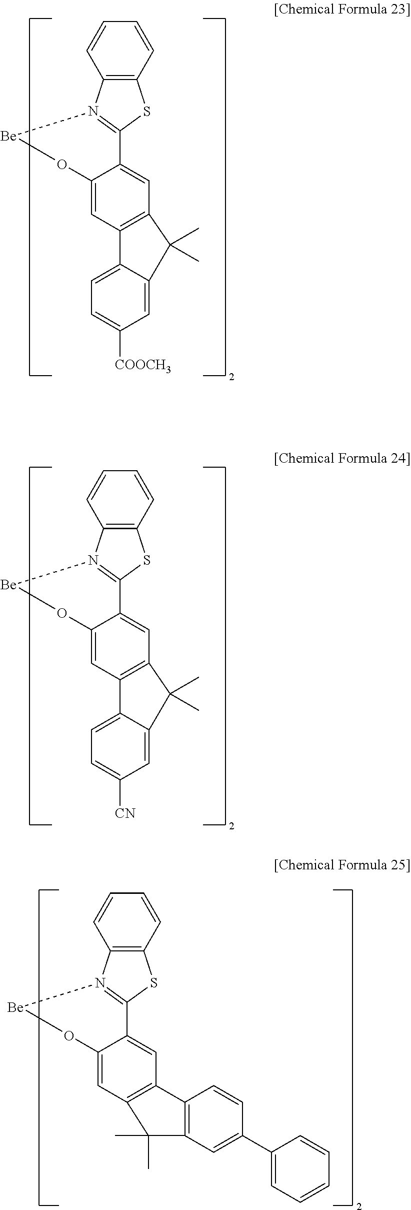

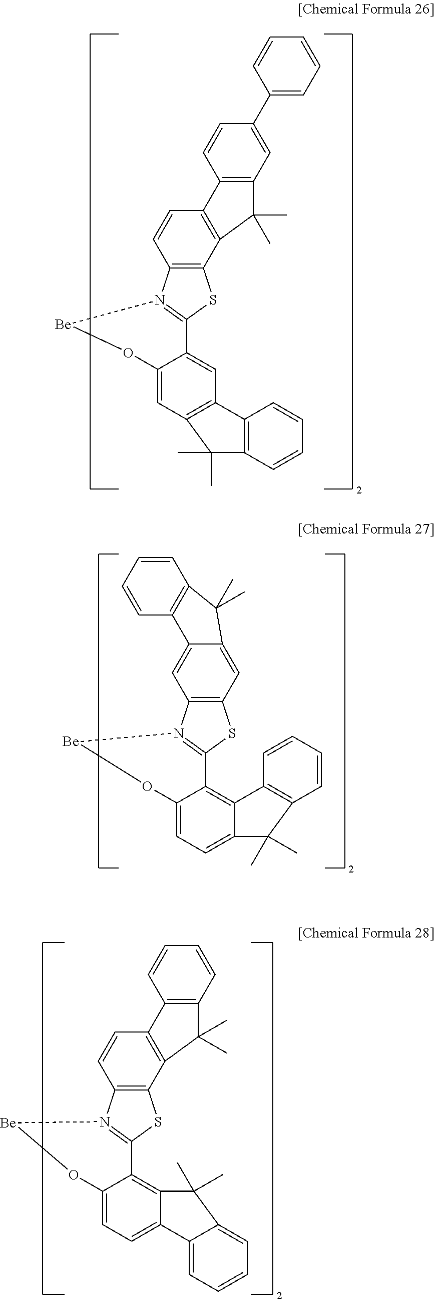

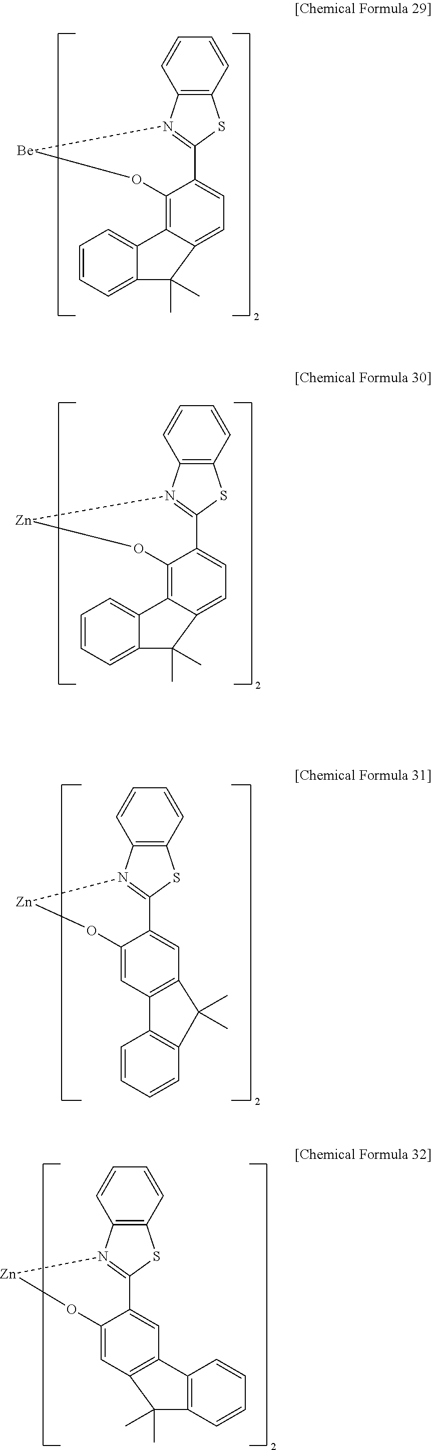

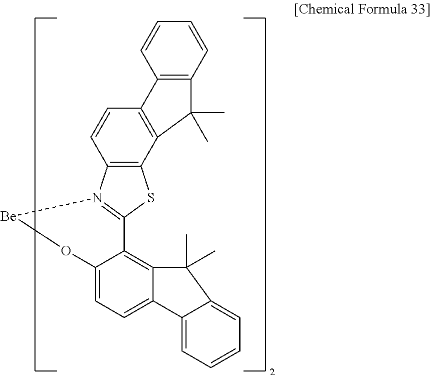

The organic material may further include a dopant material.

An organic material for an organic light emitting device having improved carrier transport capability is provided.

An organic light emitting device including the organic material has improved driving voltage characteristics and luminous efficiency.

### BRIEF DESCRIPTION OF THE DRAWING

FIG. 1 is a view showing an organic light emitting device including an organic material according to one embodiment.

### DETAILED DESCRIPTION

Hereinafter, organic materials and organic light emitting devices including the same are described. The following embodiments are provided so that a person of ordinary skill in the art may understand this disclosure but the invention is not limited thereto. As those skilled in the art would realize, the described embodiments may be modified in various different ways, all without departing from the spirit or scope of this disclosure.

As used herein, when a definition is not otherwise provided, the term “substituted” refers to one substituted with a C1 to C30 alkyl group; a C1 to C10 alkylsilyl group; a C3 to C30 cycloalkyl group; a C6 to C30 aryl group; a C2 to C30 heteroaryl group; a C1 to C10 alkoxy group; a fluoro group, a C1 to C10 trifluoroalkyl group such as a trifluoromethyl group; or a cyano group.

As used herein, when a definition is not otherwise provided, the term “hetero” refers to a compound or a substituent including 1 to 3 heteroatoms selected from the group consisting of N, O, S, and P, and the remaining being carbons.

As used herein, when a definition is not otherwise provided, the term “combination thereof” refers to one including two or more substituents linked by a linker, or two or more substituents combined with each other.

As used herein, when a definition is not otherwise provided, the term “alkyl group” refers to “a saturated alkyl group” without an alkene group or an alkyne group; or “an unsaturated alkyl group” including at least one alkene group or alkyne group. The “alkene group” refers to a substituent including at least one carbon-carbon double bond, and the “alkyne group” refers to substituent including at least one carbon-carbon triple bond. The alkyl group may be branched, linear, or cyclic alkyl group.

The alkyl group may be a C1 to C20 alkyl group.

For example, a C1 to C4 alkyl group includes 1 to 4 carbon atoms in an alkyl chain and may be selected from the group consisting of methyl, ethyl, propyl, iso-propyl, n-butyl, iso-butyl, sec-butyl, and t-butyl.

Examples of the alkyl group include a methyl group, an ethyl group, a propyl group, an isopropyl group, a butyl group, an isobutyl group, a t-butyl group, a pentyl group, a hexyl group, an ethenyl group, a propenyl group, a butenyl group, a cyclopropyl group, a cyclobutyl group, a cyclopentyl group, a cyclohexyl group, and the like.

The “aromatic group” includes cyclic structures where all elements have p-orbitals which form conjugation. For example, an aryl group and a heteroaryl group may be exemplified.

The term “aryl group” includes monocyclic or fused cyclic groups, that is to say, a plurality of cyclic substituents sharing adjacent carbon atoms.

The “heteroaryl group” refers to an aryl group 1 to 3 heteroatoms selected from the group consisting of N, O, S, and P, and the remaining being carbons. When the aryl group is a fused ring, each ring may include 1 to 3 hetero atoms.

In this specification, the term “and/or” refers to at least one of the listed constituent elements. In this specification, constituent elements and/or portions are depicted using the words “first, second, and the like,” which are used for definite description.

In this specification, it will be understood that when one constituent element is referred to as being “on” another constituent elements, it can be directly on the other element or intervening elements may also be present.

In the drawings, the thicknesses of constituent elements are exaggerated for clarity. The terms indicating positions such as “upper” and “under” are used for definite description of relative positions, and do not indicate absolute positions of constituent elements.

An organic material according to one embodiment is described. The organic material may be used for an organic emission layer, an auxiliary layer, or a combination thereof, for an organic light emitting device. The auxiliary layer may include a hole transport layer (HTL), a hole injection layer (HIL), an electron injection layer (EIL), an electron transport layer (ETL), or a combination thereof.

The organic material may include a chelate metal complex. The organic material includes a compound represented by Chemical Formula 1.

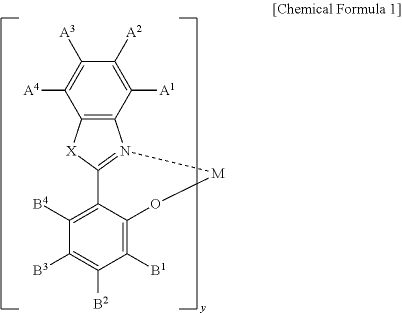

In Chemical Formula 1, A¹, A², A³, A⁴, B¹, B², B³ and B⁴ are independently selected from hydrogen, a C1 to C20 alkyl group, a C1 to C20 alkenyl group, an amino group, a C1 to C20 ether group, a C1 to C20 carboxyl group, a C1 to C20 ester group, a nitro group, a cyano group, a C3 to C30 aromatic group and a halogen-containing group. In Chemical Formula 1, M is divalent or trivalent metal ions selected from beryllium (Be), magnesium (Mg), zinc (Zn), calcium (Ca), chromium (Cr), iron (Fe), cobalt (Co), nickel (Ni), copper (Cu), cadmium (Cd), gallium (Ga), aluminum (Al), indium (In), ruthenium (Ru), scandium (Sc), and yttrium (Y), and X is oxygen (O) or sulfur (S). In Chemical Formula 1, y is an integer ranging from 2 to 3.

At least one of A¹, A², A³ and A⁴ may be an aromatic group. For example, at least one of A¹, A², A³ and A⁴ may be selected from a substituted or unsubstituted phenyl group, a substituted or unsubstituted naphthyl group, a substituted or unsubstituted anthracenyl group, and a substituted or unsubstituted hetero aromatic group.

An aromatic group included in at least one of A¹, A², A³ and A⁴ forms a fused ring structure with the aromatic ring attached to the A¹ to A⁴ groups by being bound to an adjacent substituent. The fused ring may be a 5-membered ring. Through formation of a fused ring, an aromatic group included in at least one of A¹, A², A³ and A⁴ exists in substantially the same plane as the aromatic group bound to the A¹ to A⁴ groups.

In one embodiment, at least one of A¹, A², A³ and A⁴ may be a phenyl group, and a substituent adjacent to the phenyl group may be an isopropyl group. Alpha carbon of the phenyl group may be linked to alpha carbon of the isopropyl group to form a 5-membered ring structure. That is to say, the compound may have a fluorene structure.

Similarly, at least one of B¹, B², B³ and B⁴ may be an aromatic substituent. An aromatic group included in at least one of B¹, B², B³ and B⁴ forms a fused ring structure with the aromatic ring attached to the B¹ to B⁴ groups by being bound to an adjacent substituent. Through formation of the fused ring structure, an aromatic group included in at least one of B¹, B², B³ and B⁴ exists in substantially the same plane as the aromatic group bound to the B¹ to B⁴ groups.

The aromatic group included in at least one of A¹, A², A³ and A⁴, the substituent adjacent to the aromatic group included in at least one of A¹, A², A³ and A⁴ and/or the aromatic group included in at least one of B¹, B², B³ and B⁴ and the substituent adjacent to the aromatic group included in at least one of B¹, B², B³ and B⁴ may be represented by the following Chemical Formulas 2 or 3.

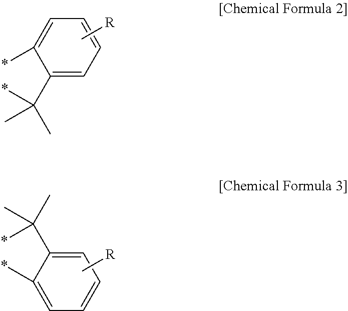

In Chemical Formula 2 and Chemical Formula 3, R is selected from hydrogen, a C1 to C10 alkyl group, an amino group, a C1 to C10 alkyl amino group, a halogen, a hydroxy group, a C1 to C10 alkoxy group, a C2 to C10 ester group, a nitro group, a cyano group, and a substituted or unsubstituted C3 to C24 aromatic group.

The fused ring structure of the substituents may be formed between only at least one of A¹ to A⁴ and adjacent substituents thereto, or between only at least one of B¹ to B⁴ and adjacent substituents thereto. The fused ring structure of the substituents may be formed both between at least one of A¹ to A⁴ and adjacent substituents thereto, and at least one of B¹ to B⁴ and adjacent substituents thereto.

For example, the organic material according to one embodiment may include at least one of the compounds represented by the following Chemical Formulae 4 to 33.

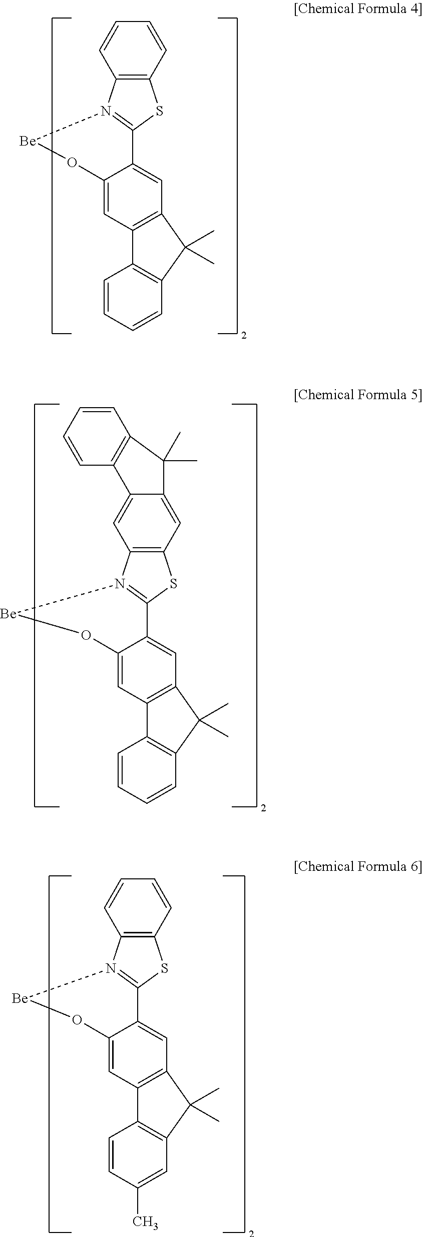

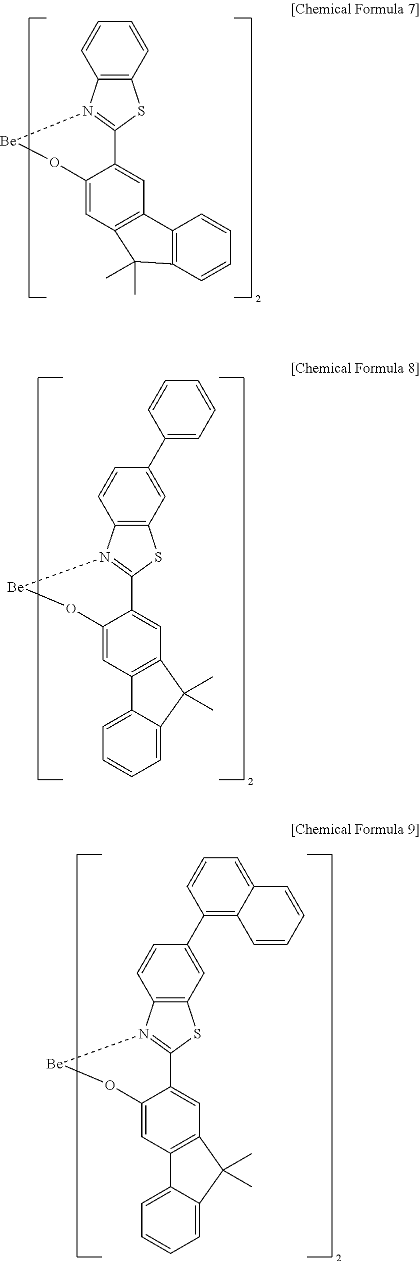

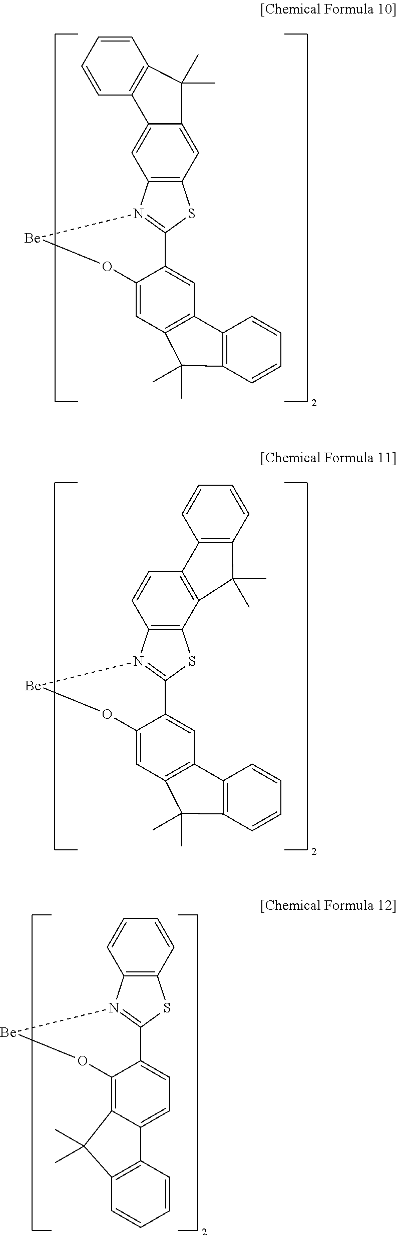

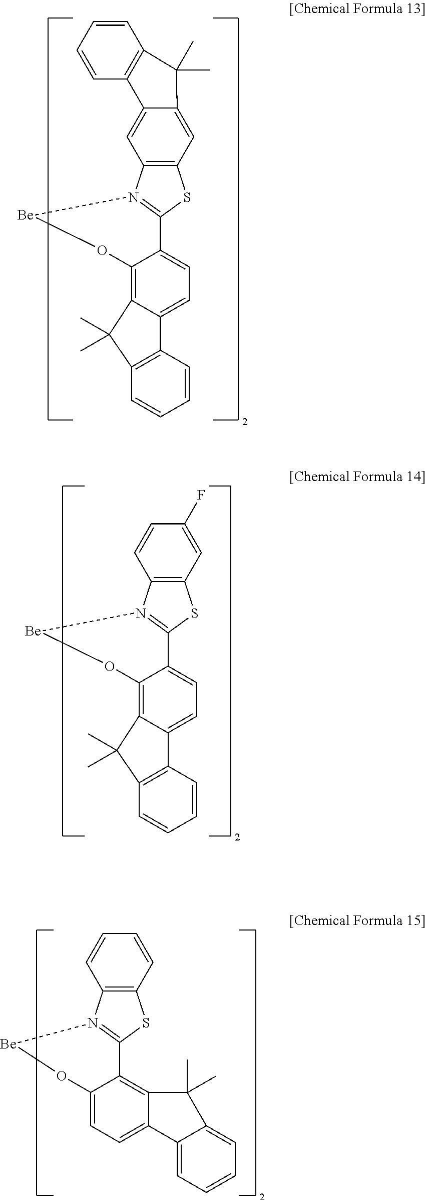

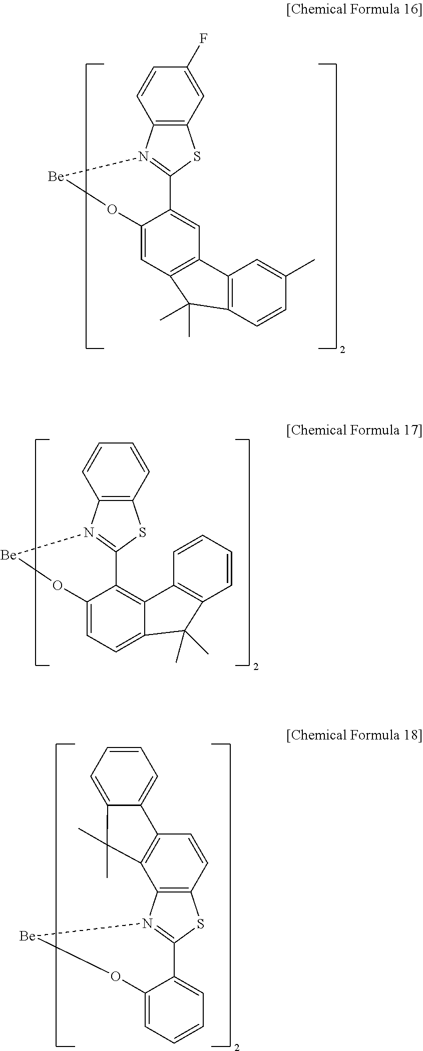

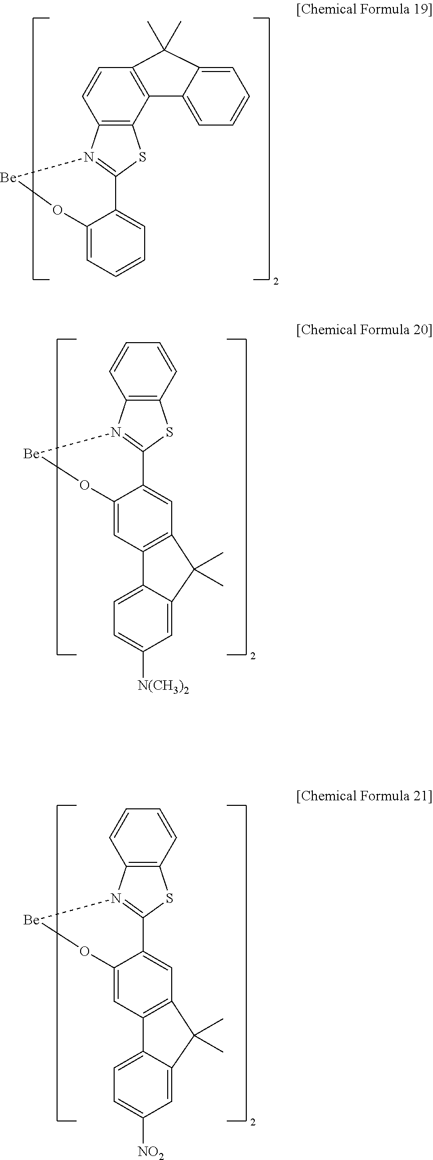

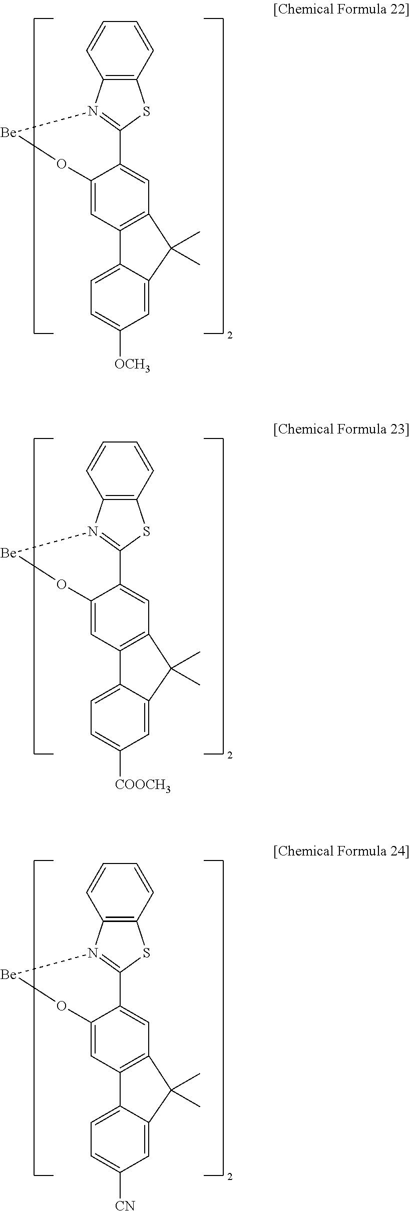

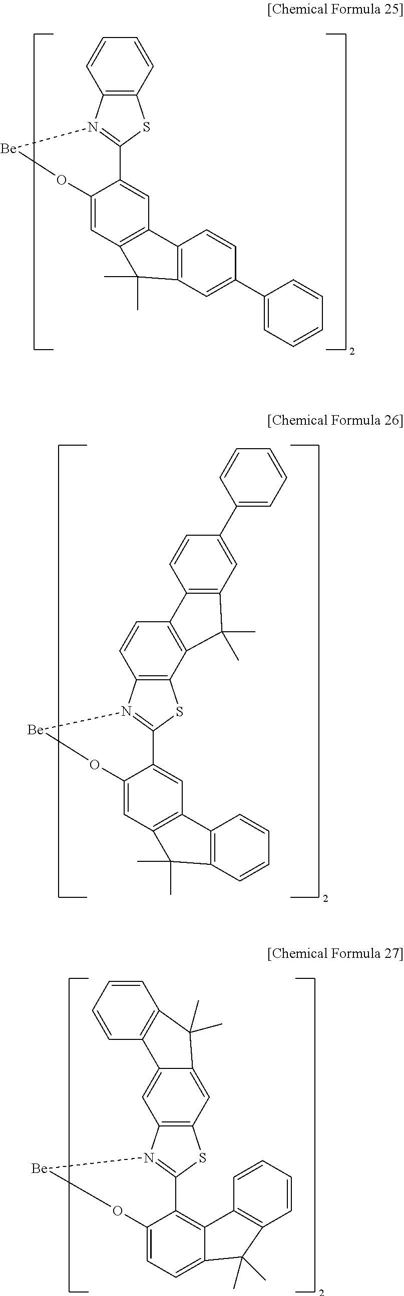

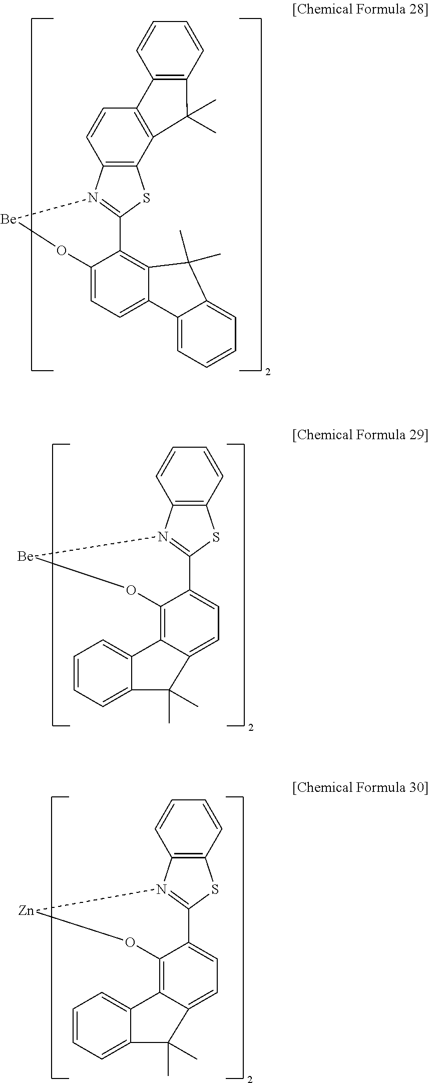

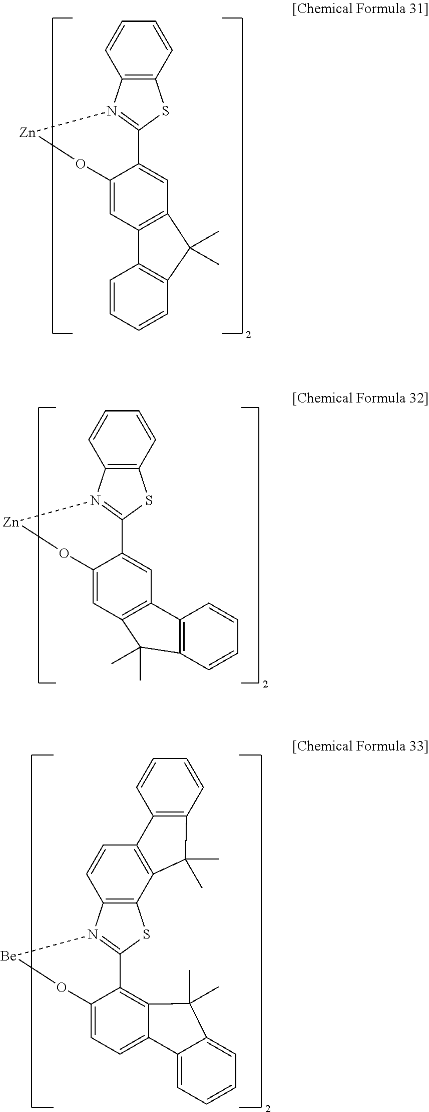

The organic material according to one embodiment may have high carrier transport capability. As described above, through formation of the fused ring structure, the two or more aromatic groups in the compounds may be positioned in substantially the same plane. Through the planar structure and aromatic groups, pi-electron systems in the compounds may be extended. Thereby, the organic material including the compound may have improved carrier transport capability.

The organic material may further include a dopant material. Examples of the dopant material may include tris(1-phenylisoquinoline)iridium (Ir(piq)₃), bis bis(1-(phenyl)isoquinoline)iridium(III) acetylanetonate (Ir(phq)₂acac), platanium (II) octaethylporphine (Pt(II) octaethylporphine, PtOEP), fac-tris(2-phenylpyridine)iridium (Ir(ppy)₃), tris(2-(1-cyclohexenyl)pyridine)iridium (Ir(chpy)₃), tris(2-(3-methyl-1-cyclohexenyl)pyridine)iridium (Ir(mchpy)₃), iridium(III) bis(4′,6′-difluorophenylpyridinato)tetrakis (1-pyrazoyl) borate (Fir6), or a combination thereof.

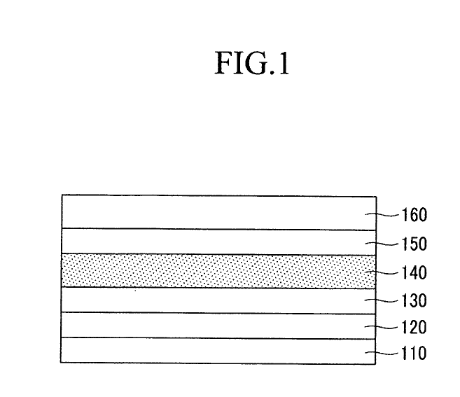

Referring to FIG. 1, an organic light emitting device including the organic material is described.

FIG. 1 is a cross-sectional view showing an organic light emitting device according to one embodiment.

Referring to FIG. 1, the organic light emitting device includes a lower electrode 120, an upper electrode 160, and an organic emission layer 140 disposed between the lower electrode 120 and upper electrode 160. A lower auxiliary layer 130 may be interposed between the lower electrode 120 and the organic emission layer 140. An upper auxiliary layer 150 may be interposed between the organic emission layer 140 and the upper electrode 160.

The substrate 110 may include glass, a polymer, or a combination thereof.

At least one of the lower electrode 120 and upper electrode 160 may be a cathode and the other one may be an anode. The lower electrode 120 and the upper electrode 160 may be transparent or opaque electrodes. For example, the lower electrode 120 and the upper electrode 160 may include ITO, IZO, or a combination thereof, or aluminum (Al), silver (Ag), or a combination thereof.

At least one of the lower auxiliary layer 130 and the upper auxiliary layer 150 may include a hole injection layer (HIL) and/or a hole transport layer (HTL), and the other one may include an electron transport layer (ETL) and/or an electron injection layer (EIL). For example, when the lower electrode 120 is an anode and the upper electrode 150 is a cathode, the lower auxiliary layer 130 may include a hole injection layer (HIL) and/or a hole transport layer (HTL) and the upper auxiliary layer 150 may include an electron injection layer (EIL) and/or an electron transport layer (ETL). However, at least one of the lower auxiliary layer 130 and the upper auxiliary layer 150 may be omitted.

The organic emission layer 140 may include the organic material. The organic material may include a compound represented by Chemical Formula 1.

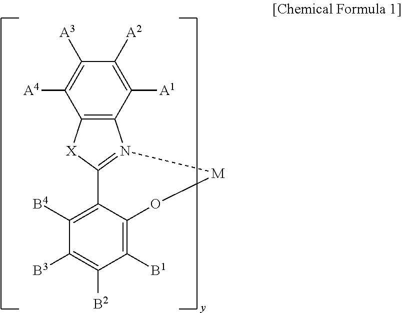

In Chemical Formula 1, A¹, A², A³, A⁴, B¹, B², B³ and B⁴ are independently selected from hydrogen, a C1 to C20 alkyl group, a C1 to C20 alkenyl group, an amino group, a C1 to C20 ether group, a C1 to C20 carboxyl group, a C1 to C20 ester group, a nitro group, a cyano group, a C3 to C30 aromatic group, and a halogen-containing group. In Chemical Formula 1, M is a divalent or trivalent metal ion, for example, beryllium (Be), magnesium (Mg), zinc (Zn), calcium (Ca), chromium (Cr), iron (Fe), cobalt (Co), nickel (Ni), copper (Cu), cadmium (Cd), gallium (Ga), aluminum (Al), indium (In), ruthenium (Ru), scandium (Sc), and yttrium (Y), and X is oxygen (O) or sulfur (S). In Chemical Formula 1 y is 2 or 3.

At least one of A¹, A², A³ and A⁴ is an aromatic group. An aromatic group included in at least one of A¹, A², A³ and A⁴ forms a fused ring by being bound to an adjacent substituent. The fused ring may be 5-membered ring.

Through formation of the fused ring, an aromatic group included in at least one of A¹, A², A³ and A⁴ exists in e substantially the same plane as an aromatic group bound to the A¹ to A⁴.

In one embodiment, at least one of A¹, A², A³ and A⁴ may be a phenyl group, and a substituent adjacent to the phenyl group may be an isopropyl group. Alpha carbon of the phenyl group may be linked to alpha carbon of the isopropyl group to form a 5-membered ring structure. That is to say, the compound may have a fluorene structure.

Similarly, at least one of B¹, B², B³ and B⁴ may be an aromatic substituent. An aromatic group included in at least one of B¹, B², B³ and B⁴ forms a fused ring structure by being bound to an adjacent substituent. Through formation of the fused ring structure, an aromatic group included in at least one of B¹, B², B³ and B⁴ exists in substantially the same plane as the aromatic group bound to the B¹ to B⁴.

The aromatic group included in at least one of A¹, A², A³ and A⁴, the substituent adjacent to the aromatic group included in at least one of A¹, A², A³ and A⁴ and/or the aromatic group included in at least one of B¹, B², B³ and B⁴ and the substituent adjacent to the aromatic group included in at least one of B¹, B², B³ and B⁴ may be represented by the following Chemical Formulas 2 or 3.

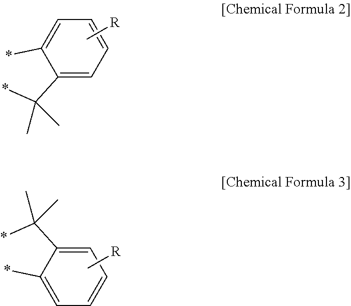

In Chemical Formula 2 and Chemical Formula 3R is selected from hydrogen, a C1 to C10 alkyl group, an amino group, a C1 to C10 alkyl amino group, a hydroxy group, a C1 to C10 alkoxy group, a C2 to C10 ester group, a nitro group, a halogen, a cyano group, and a substituted or unsubstituted C3 to C24 aromatic group.

The fused ring between the substituents may be applied to only A¹ to A⁴ or only B¹ to B⁴. The fused ring between the substituents may be applied to A¹ to A⁴ and B¹ to B⁴.

For example, the organic material according to one embodiment includes at least one of the compounds represented by the following Chemical Formulae 4 to 33.

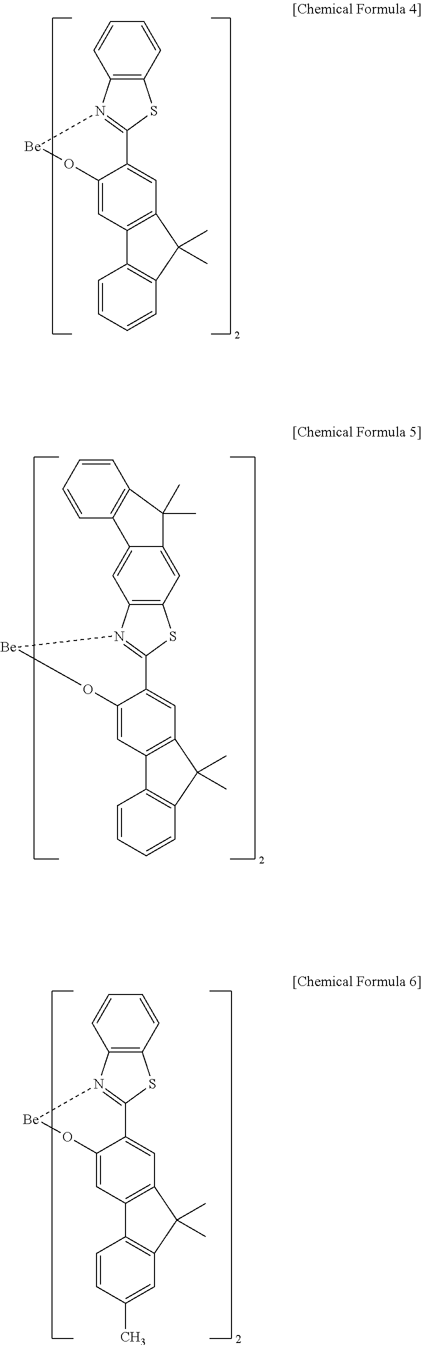

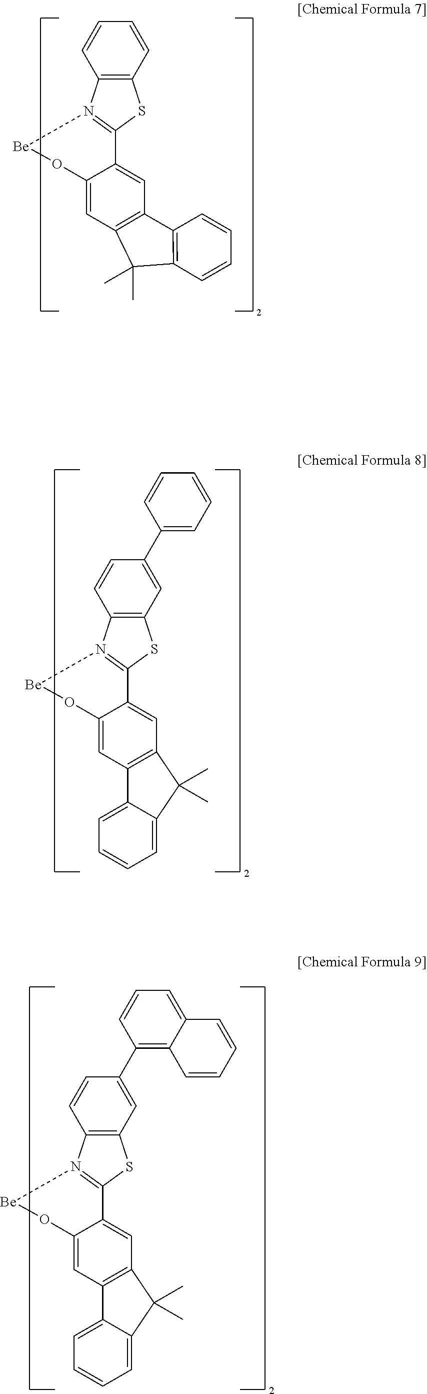

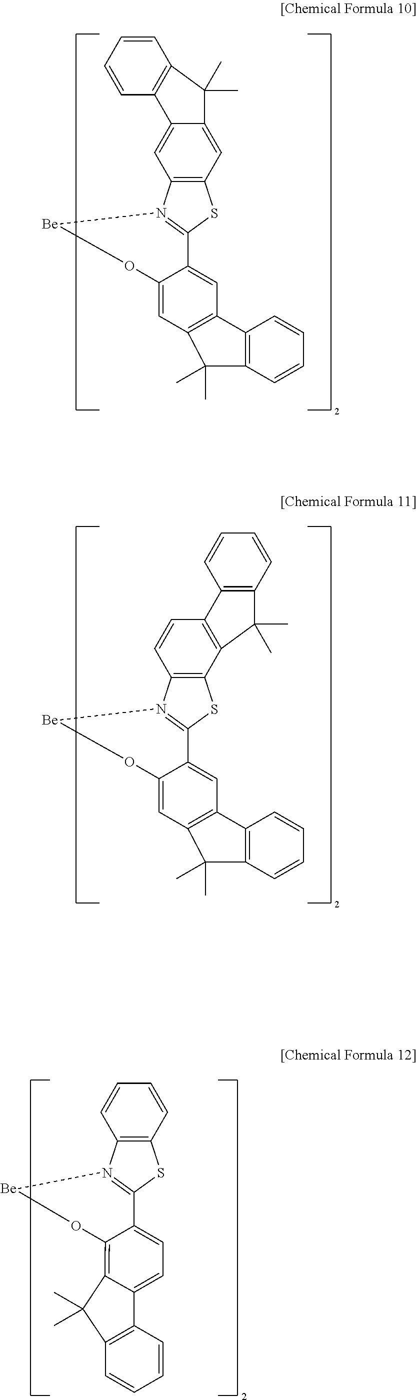

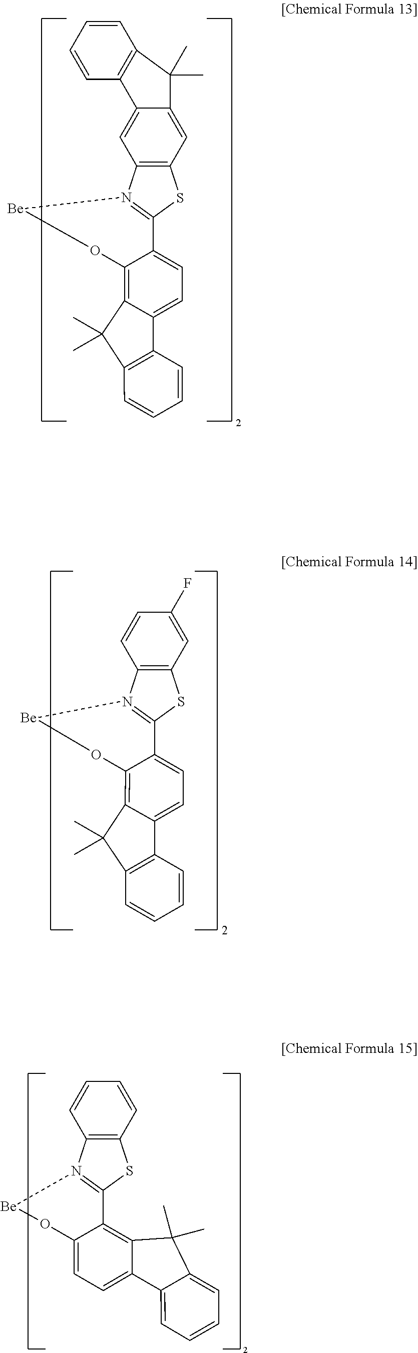

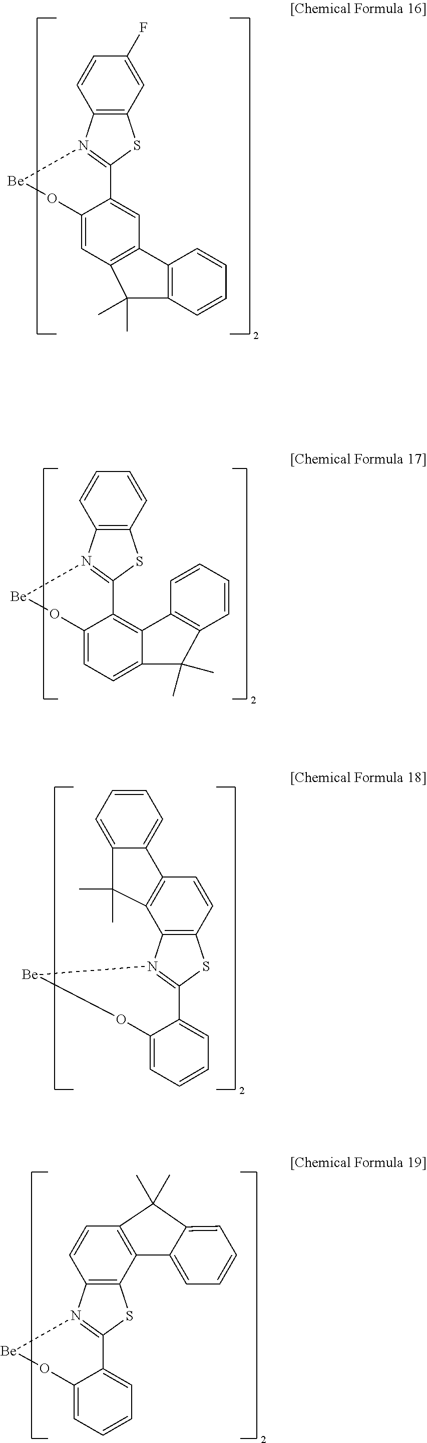

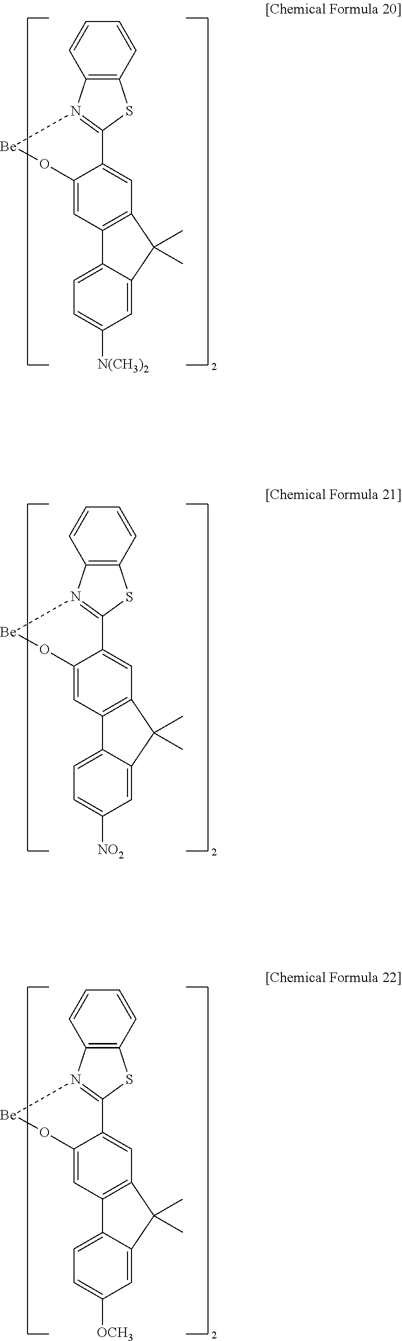

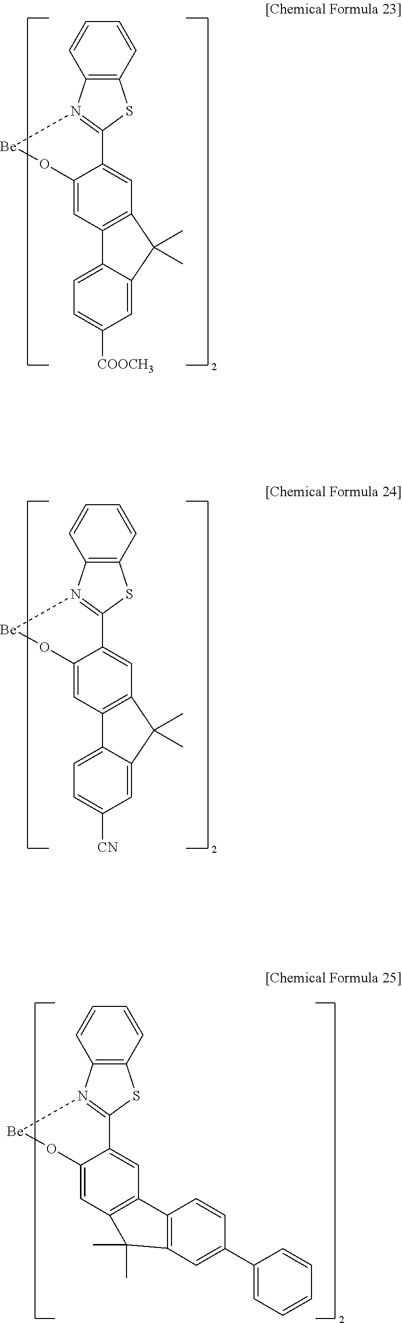

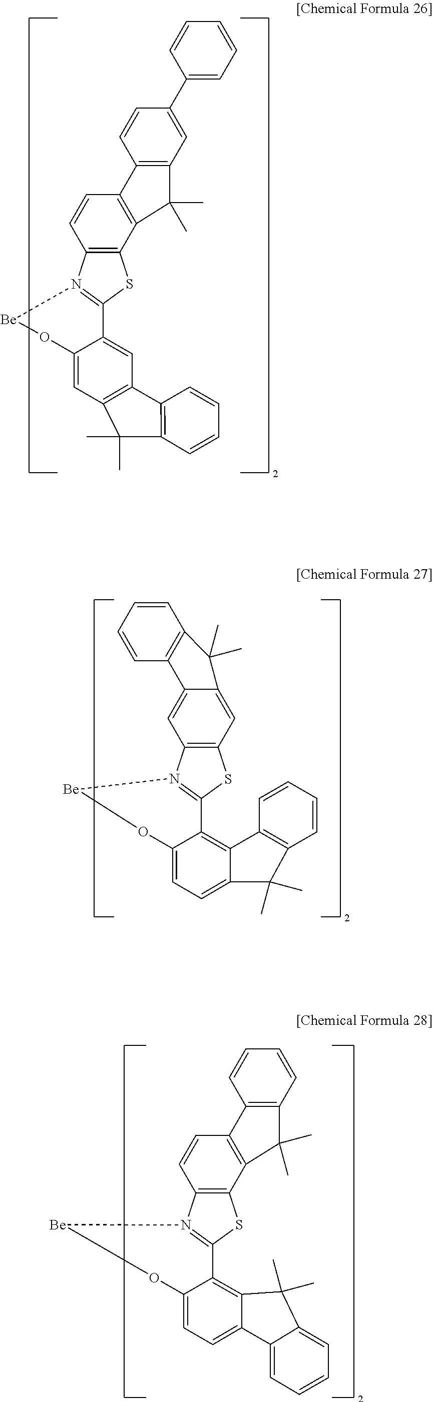

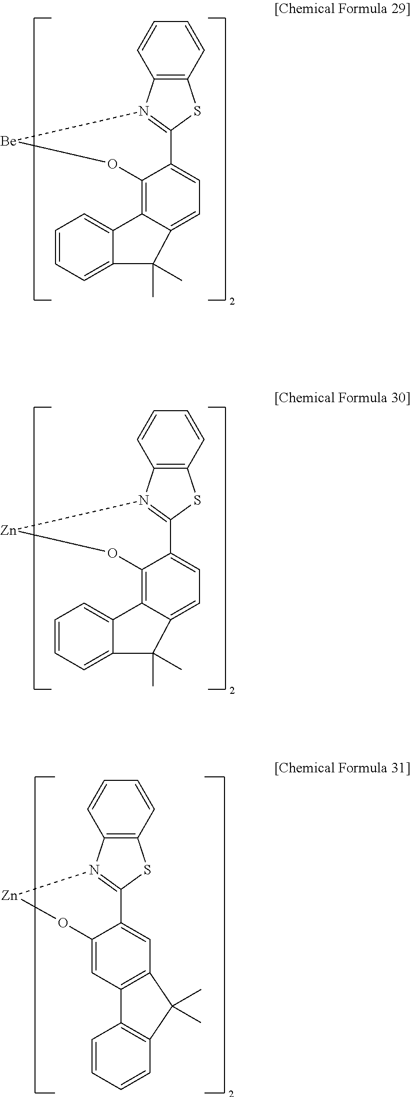

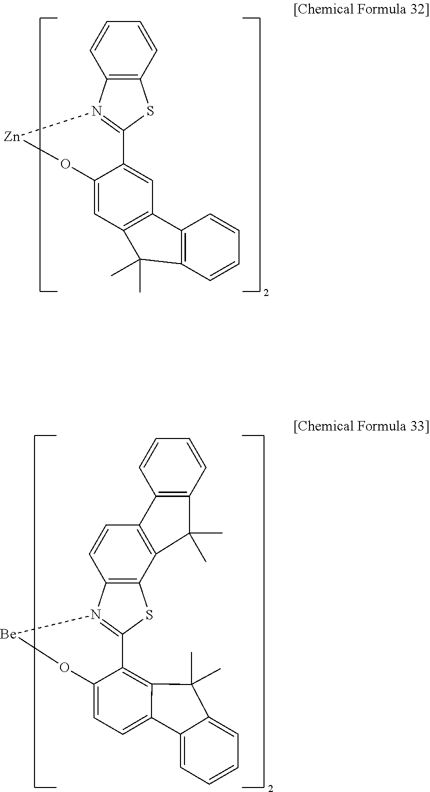

The organic material according to one embodiment may improve performance of an organic light emitting device. In particular, the compound of the organic material includes a pi-electron system that improves carrier transport capability of the compound. Accordingly, the organic light emitting device including the organic emission layer may have improved driving voltage characteristics and luminous efficiency.

The organic material may further include a red dopant material, a green dopant material, a blue dopant material, or a combination thereof. Examples of the dopant material may include tris(1-phenylisoquinoline)iridium (Ir(piq)₃), bis(1-(phenyl)isoquinoline)iridium(III) acetylanetonate (Ir(phq)₂acac), platanium (II) octaethylporphine (Pt(II) octaethylporphine, PtOEP), fac-tris(2-phenylpyridine)iridium (Ir(ppy)₃), tris(2-(1-cyclohexenyl)pyridine)iridium (Ir(chpy)₃), tris(2-(3-methyl-1-cyclohexenyl)pyridine)iridium (Ir(mchpy)₃), iridium(III) bis[(4,6-difluorophenyl)pyridinato-N,C-2′]picolinate (FIrpic), iridium(III) bis(4′,6′-difluorophenylpyridinato)tetrakis (1-pyrazoyl) borate (Fir6), or a combination thereof.

The following examples illustrate this disclosure in more detail. These examples, however, are not in any sense to be interpreted as limiting the scope of this disclosure.

### Preparation of Organic Light Emitting Device-1

### Example 1

An Ag/ITO layer was formed on a glass substrate, and patterned to form a lower electrode. 70 nm of N4,N4′-diphenyl-N4,N4′-bis(9-phenyl-9H-carbazol-3-yl)biphenyl-4,4′-diamine and 5 nm of dipyrazino[2,3-f:2′,3′-h]quinoxaline hexacarbonitrile (HAT-CN) were laminated on the lower electrode as a hole injection layer (HIL). 100 nm of N,N′-di(1-naphtyl)-N,N′ diphenyl-[1,1′-biphenyl]-4,4′-diamime, (α-NPD) was laminated as a hole transport layer (HTL).

An organic emission layer was formed by mixing the compound represented by the following Chemical Formula 4 and tris(1-phenylisoquinoline)iridium (Ir(piq)₃) as a red dopant, and laminating on the hole transport layer (HTL). Ir(piq)₃ was mixed at about 10 wt. % concentration relative to the compound of Chemical Formula 4. The organic emission layer used for this Example had a thickness of about 40 nm.

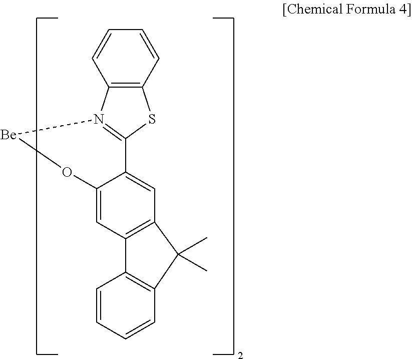

30 nm of (2-(4-(9,10-di(naphthalen-2-yl)anthracen-2-yl)phenyl)-1-phenyl-1H-benzo[d]imidazole) and 0.5 nm of lithium quinolin-8-olate were deposited on the organic emission layer. The deposited layers may be an electron transport layer (ETL) and an electron injection layer (EIL), respectively.

An upper electrode was formed on the organic emission layer by forming an Mg/Ag layer.

An organic light emitting device including a red organic emission layer was fabricated using the method described above.

### Example 2

An organic light emitting device of Example 2 including a red organic emission layer was fabricated using the same method as in Example 1, except that a compound of the following Chemical Formula 6 was used instead of the compound of Chemical Formula 4.

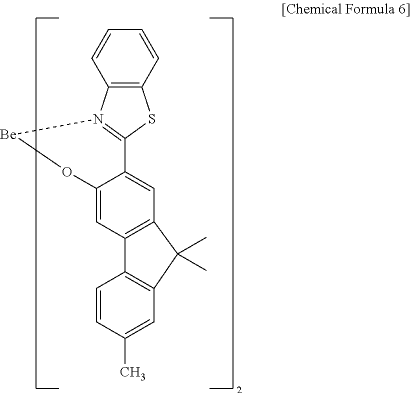

### Example 3

An organic light emitting device of Example 3 including a red organic emission layer was fabricated using the same method as in Example 1, except that a compound of the following Chemical Formula 7 was used instead of the compound of Chemical Formula 4.

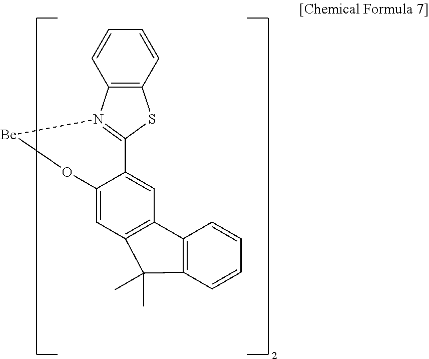

### Example 4

An organic light emitting device of Example 4 including a red organic emission layer was fabricated using the same method as in Example 1, except that a compound of the following Chemical Formula 11 was used instead of the compound of Chemical Formula 4.

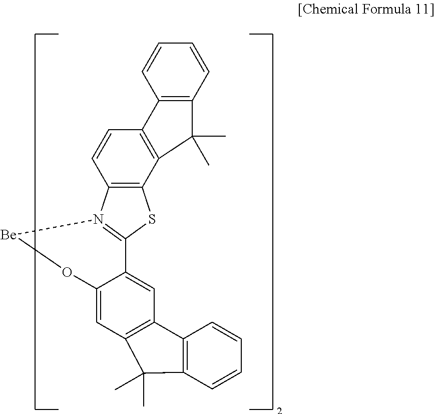

### Example 5

An organic light emitting device of Example 5 including a red organic emission layer was fabricated using the same method as in Example 1, except that a compound of the following Chemical Formula 31 was used instead of the compound of Chemical Formula 4.

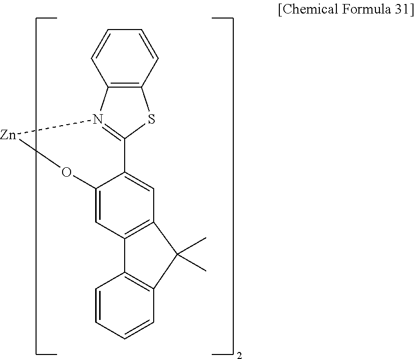

### Comparative Example 1

An organic light emitting device of Comparative Example 1 including a red organic emission layer was fabricated using the same method as in Example 1, except that biphenoxy-bi(8-hydroxy-3-methylquinoline)aluminium (BAlq) was used instead of the compound of Chemical Formula 4.

Evaluation 1

The devices of Examples 1-5 and Comparative Example 1 were measured with respect to driving voltages, efficiency, CIE color coordinates, and maximum light emitting wavelengths. The results are shown in Table 1.

TABLE 1

| | Driving | Current | | | Maximum light |
|---|---|---|---|---|---|
| | voltage | efficiency | | | emitting wave- |
| | (V) | (cd/A) | CIE x | CIE y | length (nm) |
| Example 1 | 3.7 | 28 | 0.660 | 0.340 | 624 |
| Example 2 | 3.8 | 27 | 0.659 | 0.341 | 625 |
| Example 3 | 3.6 | 30 | 0.660 | 0.339 | 624 |
| Example 4 | 3.9 | 24 | 0.661 | 0.339 | 625 |
| Example 5 | 4.2 | 23 | 0.662 | 0.337 | 625 |
| Comparative | 5.6 | 19 | 0.661 | 0.338 | 625 |
| Example 1 | | | | | |

Referring to Table 1, the organic light emitting devices of Examples 1 to 5 have lower driving voltage than the organic light emitting device of Comparative Example 1. Further, the organic light emitting devices of Examples 1 to 5 have higher current efficiency than the organic light emitting device of Comparative Example 1.

In terms of the color quality evaluated through color coordinates and maximum light emitting wavelengths, the color quality of the organic light emitting devices of Examples 1 to 5 and Comparative Example 1 are substantially equivalent to each other.

The organic light emitting devices according to the Examples emit substantially equivalent color to the organic light emitting device of the Comparative Example but with high current efficiency at a low driving voltage.

### Preparation of Organic Light Emitting Device

### Example 6

An Ag/ITO layer was formed on a glass substrate, and patterned to form a lower electrode. 70 nm of N4,N4′-diphenyl-N4,N4′-bis(9-phenyl-9H-carbazol-3-yl)biphenyl-4,4′-diamine and 5 nm of dipyrazino[2,3-f:2′,3′-h]quinoxaline hexacarbonitrile (HAT-CN) were laminated on the lower electrode as a hole injection layer (HIL). 100 nm of N,N′-di(1-naphtyl)-N,N′ diphenyl-[1,1′-biphenyl]-4,4′-diamime, (α-NPD) was laminated as a hole transport layer (HTL).

An organic emission layer was formed by mixing the compound represented by the following Chemical Formula 4 and fac-tris(2-phenylpyridine)iridium (Ir(ppy)₃) as a green dopant, and laminating the resultant on the hole transport layer (HTL). Ir(ppy)₃ was mixed at about 12 wt. % concentration relative to the compound of Formula 4. The organic emission layer used in this Example has a thickness of about 40 nm.

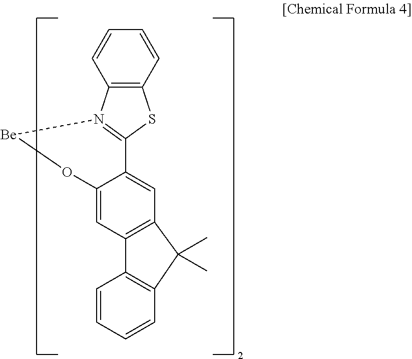

An upper electrode was formed on the organic emission layer by forming an Mg/Ag layer.

An organic light emitting device including a green organic emission layer was fabricated using the method described above.

### Example 7

An organic light emitting device including a green organic emission layer was fabricated using the same method as in Example 6 except for the organic material of an organic emission layer.

The organic emission layer of Example 7 was formed by depositing the mixture of the compound of the following Chemical Formula 7 and Ir(ppy)₃ on the hole injection layer (HIL). Ir(ppy)₃ was mixed at about 12 wt. % concentration relative to the compound of Chemical Formula 7.

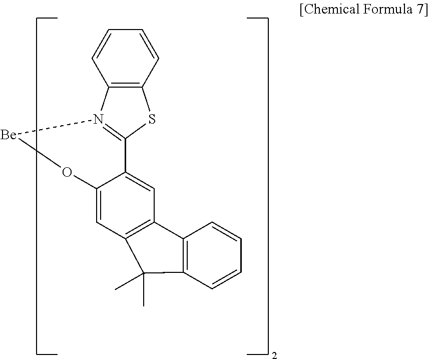

### Comparative Example 2

An organic emission layer of Comparative Example 2 was formed by depositing the mixture of 4,4′-N,N′-dicarbazole-biphenyl (CBP) and Ir(ppy)₃ on the hole injection layer (HIL). Ir(ppy)₃ was mixed at about 12 wt. % based on the CBP.

Accordingly, an organic light emitting device including a green organic emission layer was fabricated.

Evaluation 2

The devices of Examples 6 and 7 and Comparative Example 2 were measured with respect to driving voltage, efficiency, CIE color coordinates, and maximum light emitting wavelengths. The results are shown in Table 2.

TABLE 2

| | Driving | Current | | | Maximum light |
|---|---|---|---|---|---|
| | voltage | Efficiency | | | emitting wave- |
| | (V) | (cd/A) | CIE x | CIE y | length (nm) |
| Example 6 | 4.3 | 38 | 0.327 | 0.613 | 516 |
| Example 7 | 4.0 | 40 | 0.328 | 0.610 | 517 |
| Comparative | 6.1 | 33 | 0.327 | 0.611 | 517 |
| Example 2 | | | | | |

Referring to Table 2, the organic light emitting devices of Examples 6 and 7 can be operated at a lower driving voltage than the organic light emitting device of Comparative Example 2. Also, the organic light emitting devices of Examples 6 and 7 have higher current efficiency characteristics than the organic light emitting device of Comparative Example 2. Furthermore, in terms of the color quality evaluated through color coordinates and maximum light emitting wavelengths, the color quality of the organic light emitting devices of Examples 6 and 7 and Comparative Example 2 are substantially equivalent to each other.

The organic light emitting devices according to the Examples emit substantially equivalent color to the organic light emitting device of the Comparative Example but with high current efficiency at a low driving voltage.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An organic material comprising a compound of the following Chemical Formula 1: 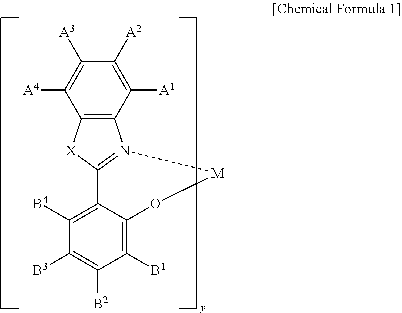
wherein, in Chemical Formula 1, A¹, A², A³, A⁴, B¹, B², B³ and B⁴ are independently selected from hydrogen, a C1 to C20 alkyl group, a C1 to C20 alkenyl group, an amino group, a C1 to C20 ether group, a C1 to C20 carboxyl group, a C1 to C20 ester group, a nitro group, a cyano group, a C3 to C30 aromatic group, and a halogen-containing group, provided that at least one of A¹ to A⁴ and at least one of B¹ to to B⁴ are a substituted or unsubstituted aromatic group and form a fused ring by being bound to an adjacent substituent,
M is a divalent or trivalent metal,
X is oxygen (O) or sulfur (S), and
y is 2 or 3.

2. The organic material of claim 1, wherein at least one of A¹ to A⁴ comprise an aromatic group which exists in the same plane as an aromatic group bound to the A¹ to A⁴.

3. The organic material of claim 2, wherein the fused ring formed by linking the aromatic group included in at least one of A¹ to A⁴ to the adjacent substituent comprises a fluorene structure.

4. The organic material of claim 1, wherein an aromatic group included in at least one of B¹ to B⁴ exists in the same plane as an aromatic group bound to the B¹ to B⁴.

5. The organic material of claim 4, wherein the fused ring formed by linking the aromatic group included in at least one of B¹ to B⁴ to the adjacent substituent comprises a fluorene structure.

6. The organic material of claim 1, wherein the aromatic group included in at least one of A¹ to A⁴ and B¹ to B⁴ and the adjacent substituent is represented by the following Chemical Formula 2 or 3. 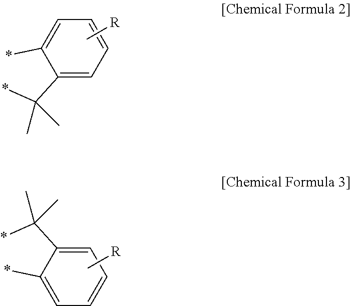
wherein, in Chemical Formulae 2 and 3, R is selected from hydrogen, a C1 to C10 alkyl group, an amino group, a C1 to C10 alkyl amino group, a hydroxy group, a C1 to C10 alkoxy group, a C2 to C10 ester group, a nitro group, a halogen, a cyano group, and a substituted or unsubstituted C3 to C24 aromatic group.

7. The organic material of claim 2, wherein the compound comprises at least one of the compounds represented by the following Chemical Formulae 4 to 33:

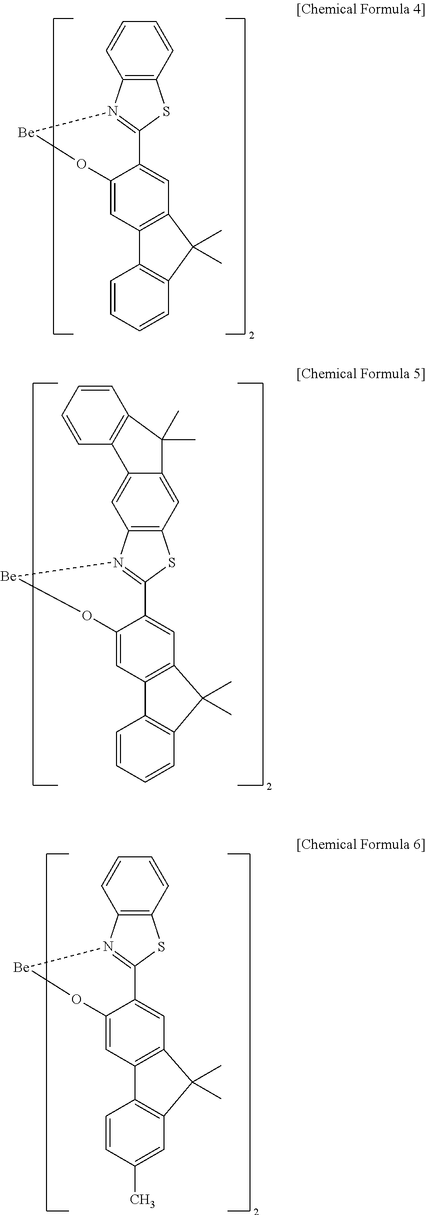

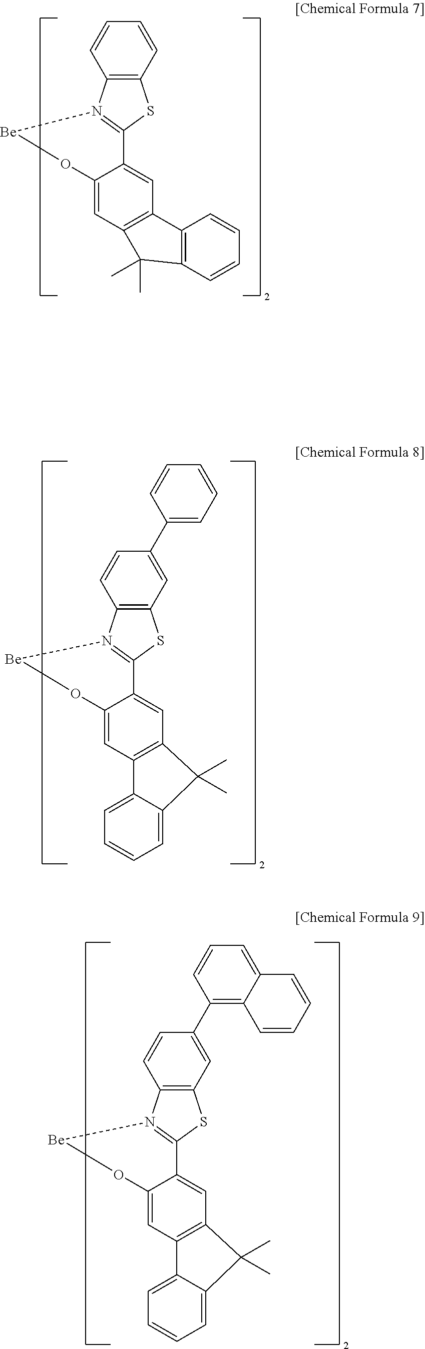

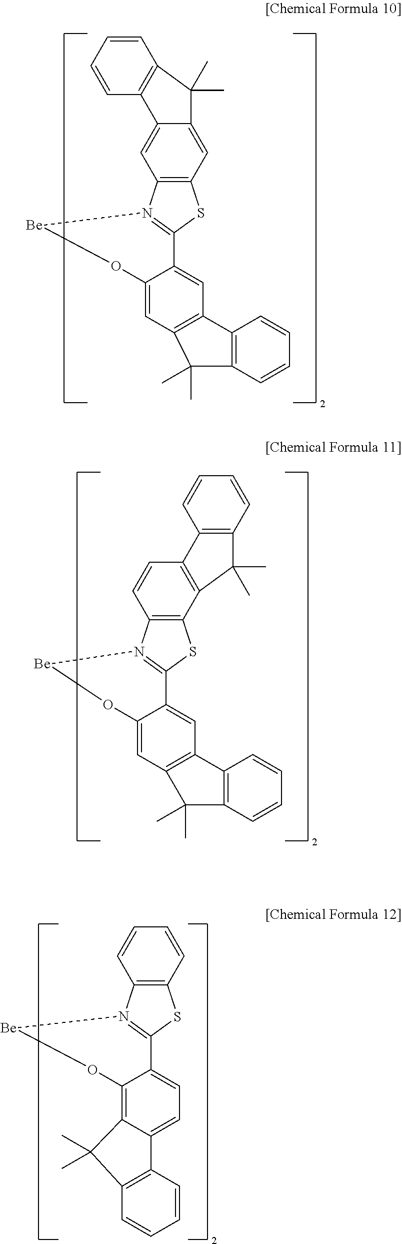

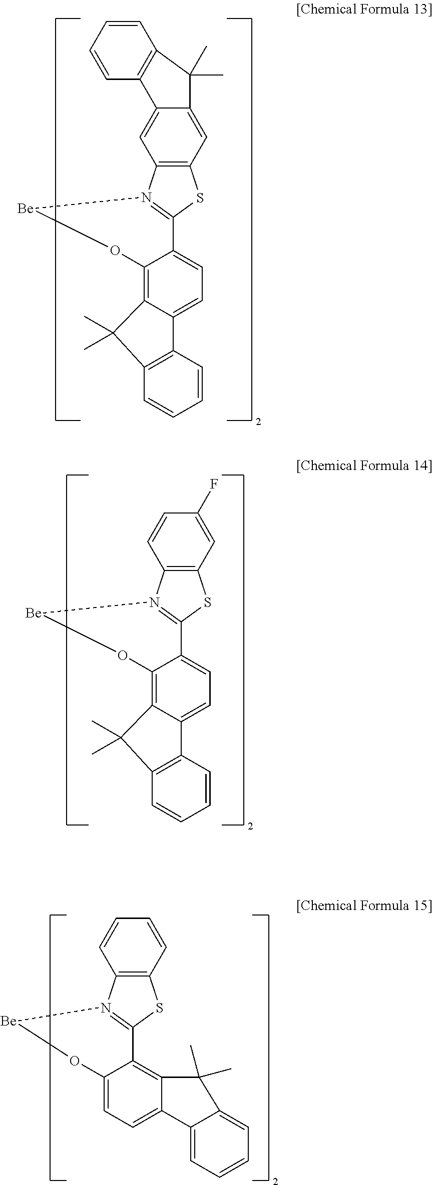

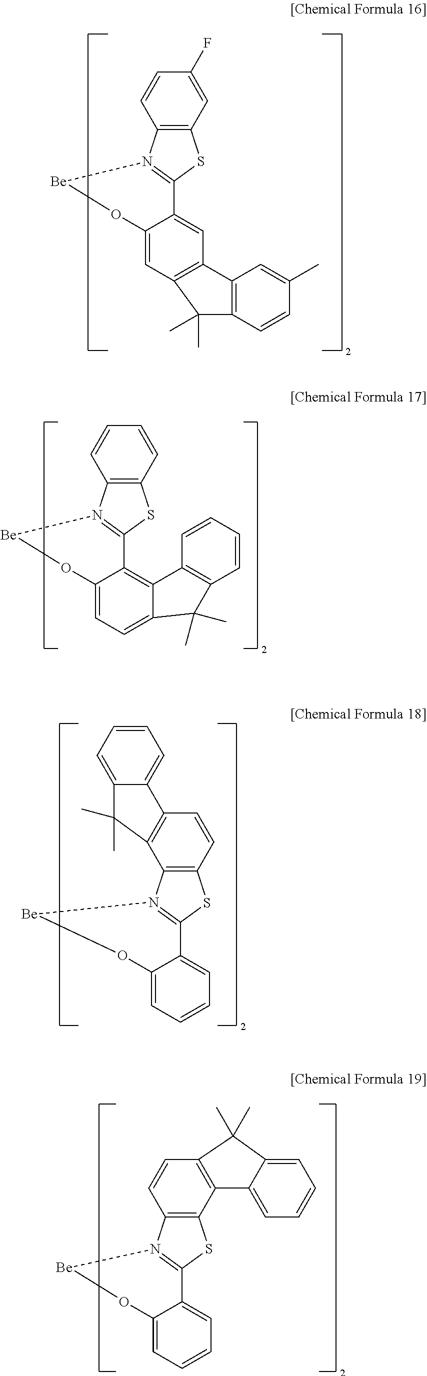

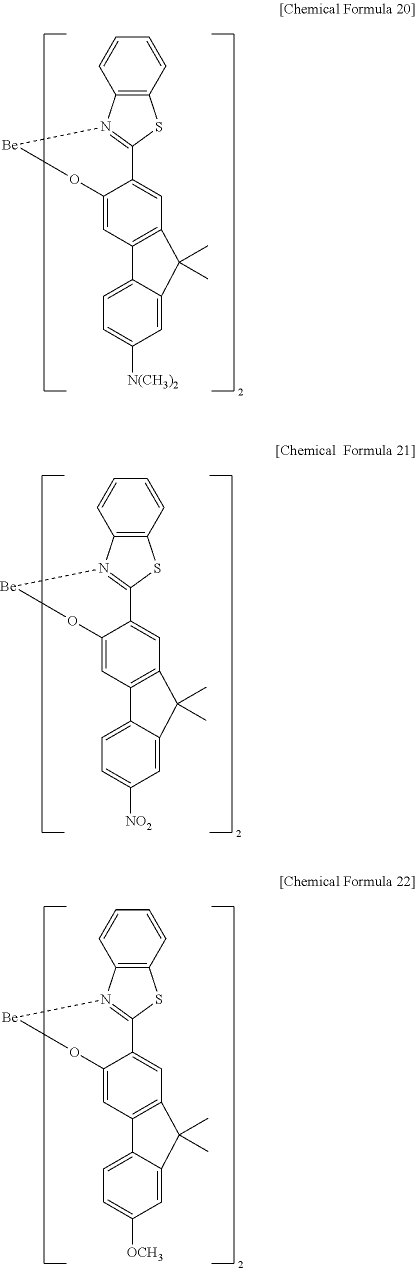

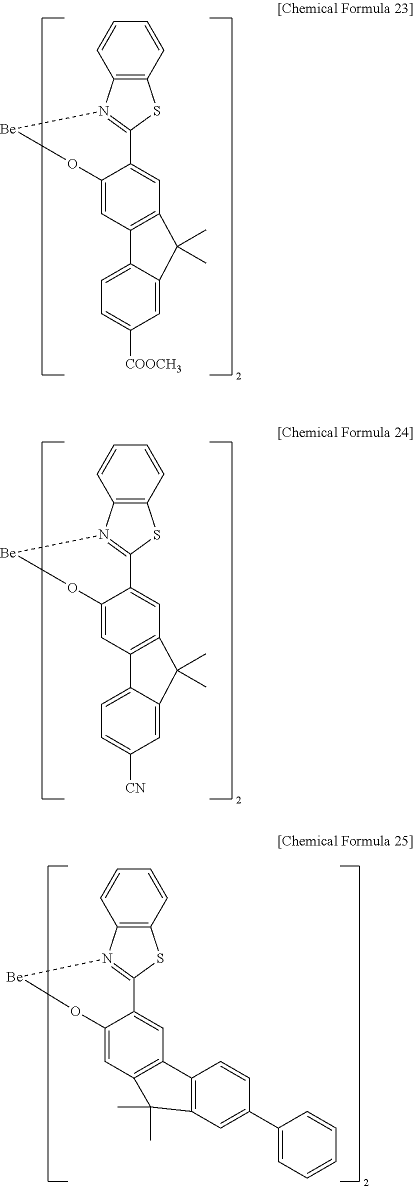

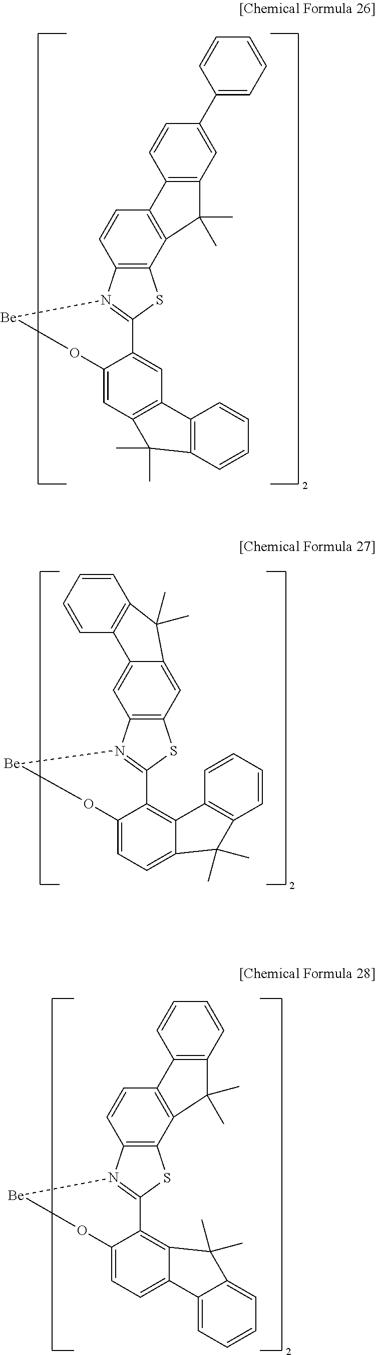

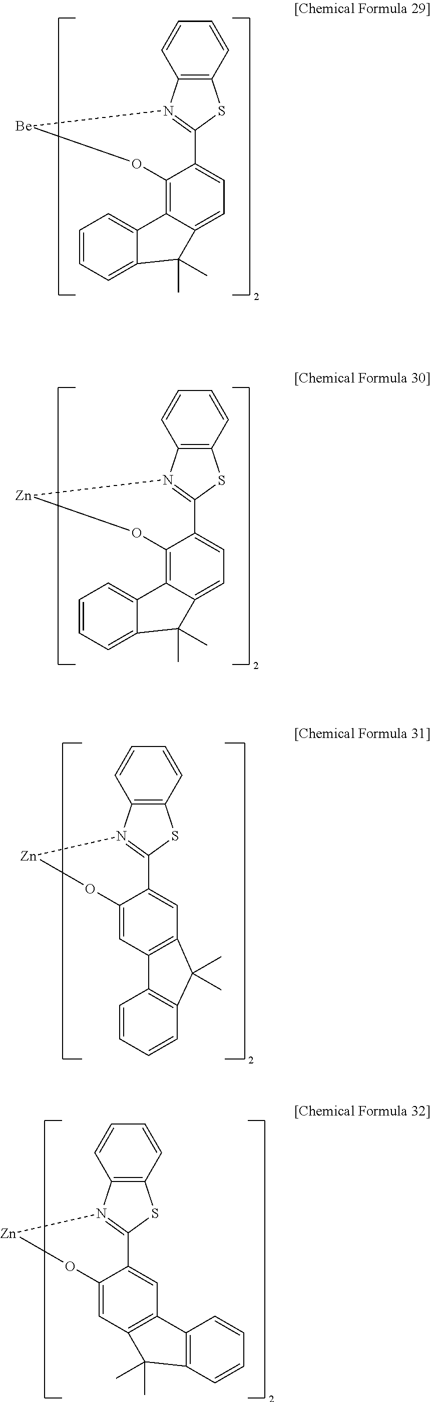

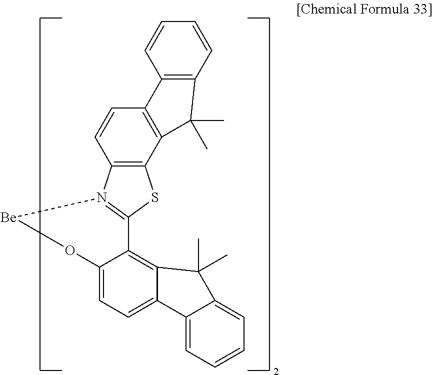

8. An organic light emitting device comprising:
a first electrode and a second electrode facing each other; and
an organic layer interposed between the first electrode and the second electrode,
the organic layer comprises a compound represented by the following Chemical Formula 1: 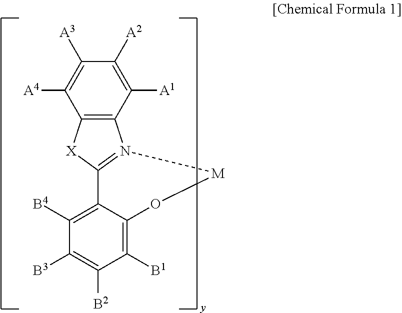
wherein, in Chemical Formula 1, A¹, A², A³, A⁴, B¹, B², B³ and B⁴ are independently selected from hydrogen, a C1 to C20 alkyl group, a C1 to C20 alkenyl to group, an amino group, a C1 to C20 ether group, a C1 to C20 carboxyl group, a C1 to C20 ester group, a nitro group, a cyano group, a C3 to C30 aromatic group, and a halogen-containing group, provided that at least one of A¹ to A⁴ and at least one of B¹ to B⁴ are a substituted or unsubstituted aromatic group and form a fused ring by being bound to an adjacent substituent,
M is a divalent or trivalent metal,
X is oxygen (O) or sulfur (S), and
y is 2 or 3.

9. The organic light emitting device of claim 8, wherein the aromatic group included in at least one of A¹ to A⁴ exists in the same plane as an aromatic group bound to the A¹ to A⁴.

10. The organic light emitting device of claim 9, wherein the fused ring formed by linking the aromatic group included in at least one of A¹ to A⁴ to the adjacent substituent comprises a fluorene structure.

11. The organic light emitting device of claim 8, wherein: the aromatic group included in at least one of B¹ to B⁴ exists in the same plane as an aromatic group bound to the B¹ to B⁴.

12. The organic light emitting device of claim 11, wherein the fused ring formed by linking the aromatic group included in at least one of B¹ to B⁴ to the adjacent substituent comprises a fluorene structure.

13. The organic light emitting device of claim 8, wherein the aromatic substituent (A^{m}) and the adjacent substituent (A^{m+1} or A^{m-1}) are represented by the following Chemical Formula 2 or 3: 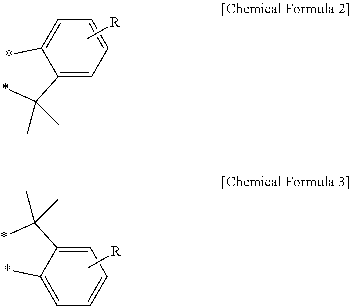
wherein, in Chemical Formulae 2 and 3, R is selected from hydrogen, a C1 to C10 alkyl group, an amino group, a C1 to C10 alkyl amino group, a hydroxy group, a C1 to C10 alkoxy group, a C2 to C10 ester group, a nitro group, a halogen, a cyano group, and a substituted or unsubstituted C3 to C24 aromatic group.

14. The organic light emitting device of claim 8, wherein the organic layer is an organic emission layer.

15. The organic light emitting device of claim 8, wherein the organic layer further comprises a dopant material.
